(19) United States
(12) Patent Application Publication
(10) Pub. No.: US 2004/0198068 A1
(43) Pub. Date: Oct. 7, 2004

(54) Method for manufacturing semiconductor device

(75) Inventor: Toru Yoshie, Chiba (JP)

Correspondence Address: LEYDIG VOIT & MAYER, LTD, 700 THIRTEENTH ST. NW, SUITE 300, WASHINGTON, DC, 20005-3960, US

(73) Assignee: Semiconductor Leading Edge Technologies, Inc., Tsukuba-shi (JP)

(21) Appl. No.: 10/803,958

(22) Filed: Mar. 19, 2004

(30) Foreign Application Priority Data
Mar. 25, 2003 (JP) 2003-082766

(51) Int. Cl. H01L 21/31

(52) U.S. Cl. 438/781

(57) ABSTRACT

An insulating film is formed on a semiconductor base material, the insulating film being predominantly composed of organic siloxane and containing an organic component which has no chemical bond to the organic siloxane. Plasma treatment is applied to the insulating film to remove the organic component and form a modifying layer on a surface of the insulating film.

### BACKGROUND OF THE INVENTION

1. Field of the Invention

The present invention relates to a method for manufacturing a semiconductor device, and more particularly to a method for manufacturing a semiconductor device including a low dielectric constant insulating film.

2. Background Art

In recent years, the speed of semiconductor devices has increased considerably, which has raised the problem of occurrence of a transmission delay due to a reduction in the signal propagation speed attributed to the wiring resistance and the parasitic capacitances between the wires and between the wiring layers in multilayered wiring portions. This problem has tended to worsen since the wiring resistance and the parasitic capacitance increase as the wiring width and the wiring pitch decrease with increasing integration density of the devices.

In order to prevent occurrence of a signal delay due to such increases in the wiring resistance and the parasitic capacitance, attempts have been made to employ copper wiring instead of aluminum wiring, as well as using low dielectric constant insulation materials as interlayer insulating films. Specifically, an example of such material is a silicon oxide film whose molecules contain fluorine or an organic group. Especially, MSQ (methyl silsesquioxane), obtained as a result of substituting S—CH₃ bonds for some of the S—O bonds of the silicon oxide film, is a promising low dielectric constant insulation material since it has a dielectric constant of as low as approximately 2.7. However, since MSQ is lacking in adhesion to the silicon oxide film formed thereon, a modifying layer is formed on the surface through plasma treatment using a gas containing oxygen to improve the adhesion.

On the other hand, there has been a need to further reduce the dielectric constant to accommodate a new generation of semiconductor devices having finer design rules. To satisfy such a need, the insulating films have been made porous. For example, MSQ may be made porous to further reduce the dielectric constant.

However, applying plasma treatment to porous MSQ oxidizes it entirely. Since the oxidized MSQ exhibits hydrophilicity, the film will contain much moisture, resulting in an increased dielectric constant.

The present invention has been devised in view of the above problems. It is, therefore, an object of the present invention to provide a method for manufacturing a semiconductor device which includes a low dielectric constant insulating film having good adhesion to a silicon oxide film.

Other objects and advantages of the present invention will become apparent from the following description.

### SUMMARY OF THE INVENTION

The present invention has been devised in view of the above problems. It is, therefore, an object of the present invention to provide a method for manufacturing a semiconductor device which includes a low dielectric constant insulating film having good adhesion to a silicon oxide film.

Other objects and advantages of the present invention will become apparent from the following description.

According to one aspect of the present invention, in a method for manufacturing a semiconductor device, an insulating film is formed on a semiconductor base material, the insulating film being predominantly composed of organic siloxane and containing an organic component which has no chemical bond to the organic siloxane. Plasma treatment is applied to the insulating film to remove the organic component and form a modifying layer on a surface of the insulating film.

In another aspect of the present invention, in a method for manufacturing a semiconductor device, an insulating film is formed on a semiconductor base material, the insulating film being composed of organic siloxane. Plasma treatment is applied to the insulating film to remove an organic group from the organic siloxane and form a modifying layer on a surface of the insulating film.

Other and further objects, features and advantages of the invention will appear more fully from the following description.

### BRIEF DESCRIPTION OF THE DRAWINGS

FIG. 1a˜1g are cross-sectional views showing a wiring forming process according to the present invention.

FIG. 2a˜2d are cross-sectional views showing a forming process of the insulating film according to the present invention.

FIG. 3a˜3d are infrared spectroscopy of the insulating film according to the present invention.

FIG. 4a˜4d are infrared spectroscopy of the insulating film according to the present invention.

FIG. 5 shows how the film thickness and the refractive index of the insulating film change with the plasma treatment time in the present invention.

FIG. 6 shows how the electric constant of the insulating film change with the plasma treatment time in the present invention.

FIG. 7 shows how the contact angle of the insulating film change with the plasma treatment time in the present invention.

FIG. 8a˜8d are infrared spectroscopy of the conventional insulating film.

FIG. 9 shows how the film thickness and the refractive index of the conventional insulating film change with the plasma treatment time.

### DETAILED DESCRIPTION OF THE PREFERRED EMBODIMENTS

A preferred embodiment of the present invention will be described below with reference to the accompanying drawings.

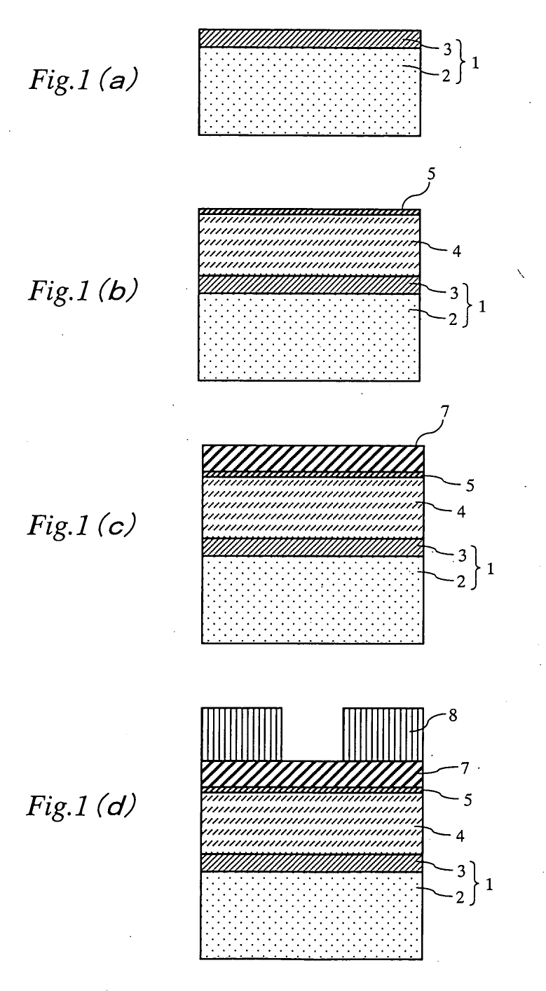

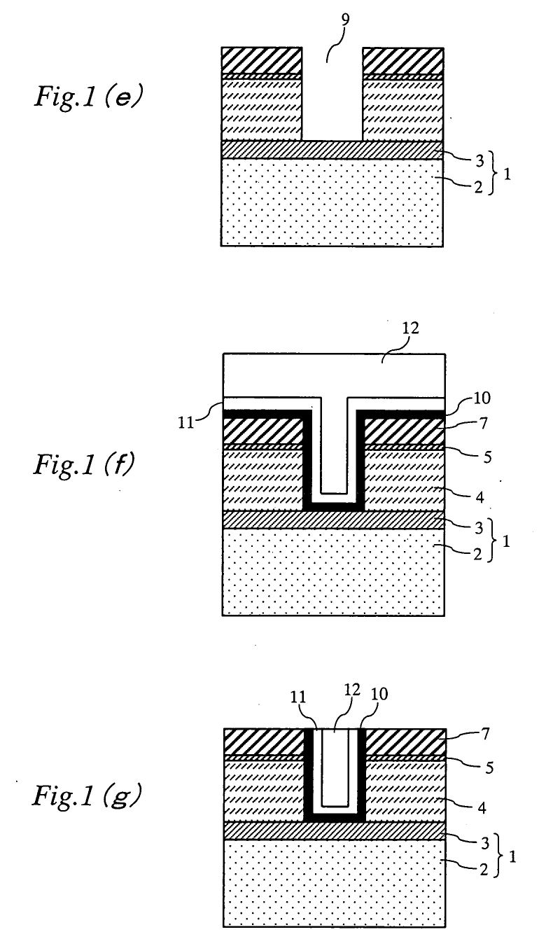

FIGS. 1A to 1G are cross-sectional views showing a wiring forming process using a damascene technique. First of all, as shown in FIG. 1A, a first insulating film 3 is formed on a silicon substrate 2, thus preparing a semiconductor base material 1. For example, a silicon carbide (SiC) film or a silicon nitride (SiN) film may be used as the first insulating film 3. These insulating films are formed on the silicon substrate using a plasma CVD (Chemical Vapor Deposition) technique.

Then, a second insulating film is formed on the semiconductor base material. According to the present embodiment, the second insulating film is an organic siloxane insulating film having a low dielectric constant and containing vacancies.

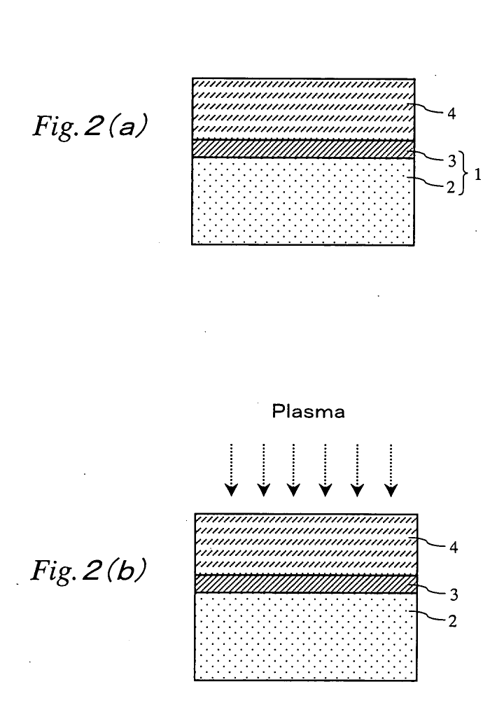

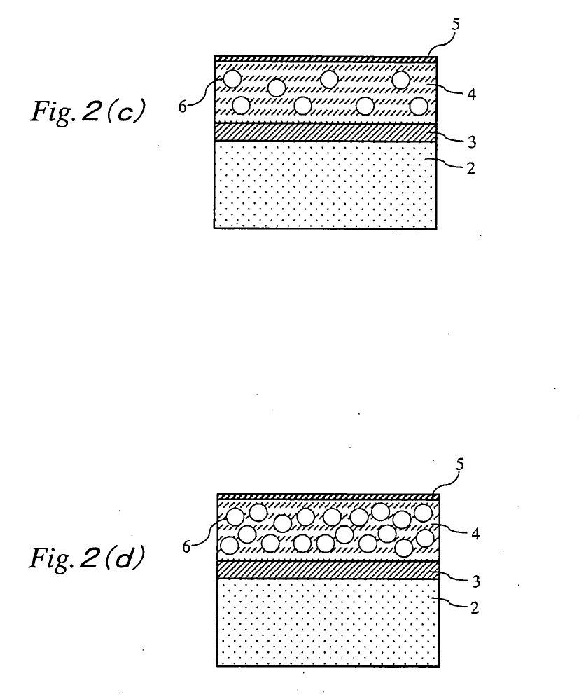

How to form the second insulating film will be described with reference to FIGS. 2A to 2D. It should be noted that components in these figures which are the same as those in FIG. 1 are denoted by like numerals.

First of all, an insulating film 4 is formed on the first insulating film 3, as shown in FIG. 2A. The insulating film 4 is predominantly composed of organic siloxane and contains an organic component which has no chemical bond to the organic siloxane.

The organic siloxane may be a siloxane whose molecules contain an alkyl group or an allyl group. Specifically, it is preferable to use MSQ (Methyl Silsesquioxane), which is obtained as a result of substituting S—CH₃ bonds for some of the S—O bonds of a silicon oxide film.

The present invention uses the above organic component to make the insulating film porous. An example of the above organic component is one which decomposes and evaporates at a lower temperature than the decomposition temperature of the organic groups constituting the organic siloxane. When such an organic component evaporates and thereby leaves the siloxane structure, a large number of vacancies can be formed within the insulating film. It should be noted that any organic component can be used if it evaporates after decomposition and leaves the siloxane structure. Therefore, examples of the organic component includes those which decompose and sublime, as well as those which decompose and evaporate.

On the other hand, the insulating film 4 may made (solely) of organic siloxane. In this case, the organic siloxane must contain an organic group which can be decomposed and thereby leave the siloxane structure. When this organic group is decomposed by heat and leaves the siloxane structure as a gas having low molecular mass, a number of vacancies are formed in the film, as in the above example. It should be noted that it may be arranged that the organic group does not directly bond to the silicon, thereby maintaining the siloxane structure even after the organic groups have left the structure through decomposition. An example of such an organic siloxane is indicated by formula 1.

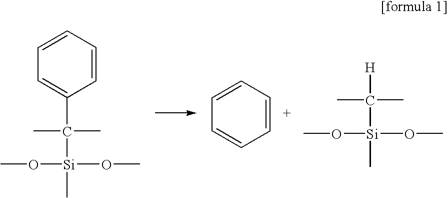

The insulating film predominantly composed of organic siloxane and containing an organic component which has no chemical bond to the organic siloxane is formed by, for example, a CVD technique using as a reaction gas a mixed gas including the organic component and organic silane.

The insulating film can also be formed using a coating technique. For example, the organic component and the organic siloxane may be dissolved in an appropriate organic solvent to prepare an insulating film composition. This composition is coated on the semiconductor base material by roll coating. It should be noted that preferably the organic siloxane employed by the present invention is a highly crosslinked organic polysiloxane, and a polymer film can be formed by removing the solvent. After coating the composition on the semiconductor base material, it is heat treated in a furnace to form a coating film. The heating temperature is preferably set to between 100° C. and 200° C. This allows removing the solvent from the insulating film composition as well as decomposing and vaporizing part of the organic component so as to form vacancies. It should be noted that the above heat treatment may be arranged to remove the solvent only in such an amount that the remaining portion of the solvent does not adversely affect the postprocess; it is not necessary to remove the entire solvent.

The insulating film made of organic siloxane containing an organic group which can be decomposed and thereby removed can also be formed using either a CVD technique or a coating technique.

Then, plasma treatment is performed on the surface of the insulating film 4, as shown in FIG. 2B.

The plasma treatment according to the present invention uses a gas containing one or more types of elements selected from a group consisting of oxygen (O), hydrogen (H), and nitrogen (N). That is, the plasma treatment may use one of oxygen gas (O₂), hydrogen gas (H₂), and nitrogen gas (N₂), or a mixture thereof. Alternatively, a gas composed of one or more elements selected from among oxygen, hydrogen, and nitrogen may be used. Specifically, exemplary gases include dinitrogen monoxide (N₂O) gas. Furthermore, these gases may contain an inert gas, such as argon (Ar) gas, as a dilution gas.

The above plasma treatment may be carried out using a common plasma treatment device. For example, the semiconductor base material on which the insulating film is formed may- be placed between the opposing electrodes disposed within the vacuum chamber of the plasma treatment device. Then, after evacuating the vacuum chamber to a predetermined vacuum level, oxygen gas is introduced into it at a predetermined flow rate, for example. With this arrangement, a high-frequency power is applied between the opposing electrodes to generate a plasma, enabling plasma treatment on the insulating film.

When the plasma treatment is performed using oxygen gas or a gas containing oxygen as a constituent element, oxygen (atoms) within the plasma is substituted for the carbon (atoms) of methyl groups in the organic siloxane constituting the insulating film. This forms a modifying layer 5 containing many S—O bonds on the surface of the insulating film 4, as shown in FIG. 2C. Furthermore, the plasma treatment decomposes the organic component contained in the insulating film. The decomposed organic component evaporates and thereby leaves the insulating film, forming vacancies 6. It should be noted that if the insulating film 4 is made of an organic siloxane containing an organic group which can be decomposed and thereby removed, the organic group portion of the organic siloxane decomposes through the plasma treatment and leaves the siloxane structure, also forming vacancies 6.

Also when a gas containing no oxygen is used to perform the plasma treatment, the organic component decomposes and evaporates (or the organic siloxane decomposes), forming vacancies 6 within the insulating film 4. The carbon atoms contained in the insulating film 4 are substituted by an element other than oxygen. For example, when hydrogen gas is used to perform the plasma treatment, hydrogen (atoms) is substituted for the carbon (atoms), and a modifying layer containing many S—H bonds is formed on the surface of the insulating film.

According to the present invention, after completing the plasma treatment, the insulating film may be heat treated at a temperature between 250° C. and 450° C. This further decomposes and vaporizes the remaining organic component within the insulating film 4, forming a large number of vacancies 6 therein, as shown in FIG. 2D. When, on the other hand, the insulating film 4 is made of an organic siloxane containing an organic group which can be decomposed and thereby removed, the above heat treatment further decomposes the organic groups. It should be noted that this heat treatment need not be carried out if the plasma treatment ensures sufficient void content.

Further according to the present invention, after completing the plasma treatment, the insulating film may be heat treated at a temperature between 400° C. and 450° C. This can cause polycondensation of silanol groups (—SiOH) within the insulating film, as described in detail below.

For example, when a gas containing oxygen is used to carry out the plasma treatment, oxygen (atoms) is substituted for carbon (atoms) within the insulating film, forming S—O bonds. Therefore, after the plasma treatment, the insulating film contains a large number of silanol groups (—SiOH), which are hydrophilic. When, on the other hand, a gas containing no oxygen is used to carry out the plasma treatment, S—H bonds and Si having dangling bonds are generated. They easily react with moisture within the insulating film, producing silanol groups. If the insulating film contains a large number of silanol groups, it becomes highly hygroscopic, resulting in an increased dielectric constant. Therefore, it is necessary to remove the silanol groups from the insulating film.

After completing the plasma treatment, the insulating film may be heat treated at a temperature between 400° C. and 450° C. to cause polycondensation reaction of the silanol groups and thereby remove them from the insulating film. This heat treatment also can remove the moisture contained in the insulating film. Thus, it is possible to prevent S—O bonds and S—H bonds within the insulating film from reacting with moisture and forming silanol groups.

Furthermore, at the same time, heat treating the insulating film at a temperature between 400 and 450° C. can promote decomposition and evaporation of the organic component contained in the insulation film (or decomposition of the organic siloxane).

Therefore, if it is intended to increase the void content of the insulating film and cause polycondensation reaction of silanol groups at the same time, the insulating film is preferably heat treated at a temperature between 400 and 450° C. after completing the plasma treatment. If, on the other hand, it is intended only to increase the void content of the insulating film, the insulating film is preferably heat treated at a temperature between 250 and 450° C. It should be noted that no heat treatment need be carried out after the plasma treatment if it is not necessary to increase the void content nor to cause polycondensation reaction of silanol groups.

Thus, decomposing and vaporizing the organic component in both the plasma and the heat treatment processes allows the organic component to be removed from the insulating film more thoroughly than when the organic component is decomposed and vaporized in only the heat treatment process. This is also true when an organic siloxane containing an organic group which can be decomposed and thereby removed is used as the insulating film. The above arrangement can produce an insulating film having a further reduced dielectric constant since the dielectric constant of an insulating film decreases with increasing void content.

Further, since the organic component is decomposed and vaporized (or the organic siloxane is decomposed) in two stages, the temperature of the heat treatment process may be set lower than that for conventional heat treatments. Reducing the heating temperature can prevent degradation of the characteristics of the semiconductor device due to heating, as well as reducing cost.

The above processes form the second insulating film 4 on the first insulating film 3, as shown in FIG. 1B. The second insulating film 4 has the modifying layer 5 on the surface thereof.

Then, as shown in FIG. 1C, a third insulating film 7 is formed on the modifying layer 5. The third insulating film 7 may be a silicon oxide film and formed by use of a coating technique or a CVD technique.

Then, a resist film (not shown) is formed the third insulating film 7, and a resist pattern 8 having a desired wiring pattern is formed using a photolithographic technique, as shown in FIG. 1D. After that, the third insulating film 7, the second insulating film 4, and the first insulating film 3 are etched using the resist pattern 8 as a mask, forming a wiring groove 9, as shown in FIG. 1E.

Then, a tantalum film 10 is formed on the third insulating film 7 and the wiring groove 9 by a sputtering technique. It should be noted that a tantalum nitride film may be used instead of the tantalum film 10. Then, a copper film 11 is formed on the tantalum film 10 by a sputtering technique. After that, a copper film 12 is formed by a plating technique such that it fills the wiring groove 9, as shown in FIG. 1F. Lastly, portions of the copper films 12 and 11 and tantalum film 10 other than those on the wiring groove 9 are removed through chemical mechanical polishing, producing the structure shown in FIG. 1G.

The above process forms a wiring structure including a low dielectric constant insulating film.

Description will be made below of an example of how to form the second insulation film according to the present embodiment.

By a coating technique, an MSQ film containing an organic component is formed on a silicon nitride film formed on a silicon substrate. After heat treating the MSQ film (and other components) at a temperature of approximately 200° C., plasma treatment is applied to it using N₂O gas. For example, N₂O gas mixed with Ar gas acting as a dilution gas is introduced into a vacuum chamber maintained at a pressure of 1,000 Pa. At that time, the flow rate of the N₂O gas and that of the Ar gas are set to 200 ccm and 1,000 ccm, respectively. 13.56 MHz RF power of 200 W may be applied between the opposing electrodes to perform plasma treatment on the MSQ film. It should be noted that the temperature of the substrate is set to approximately 250° C. in the plasma treatment process.

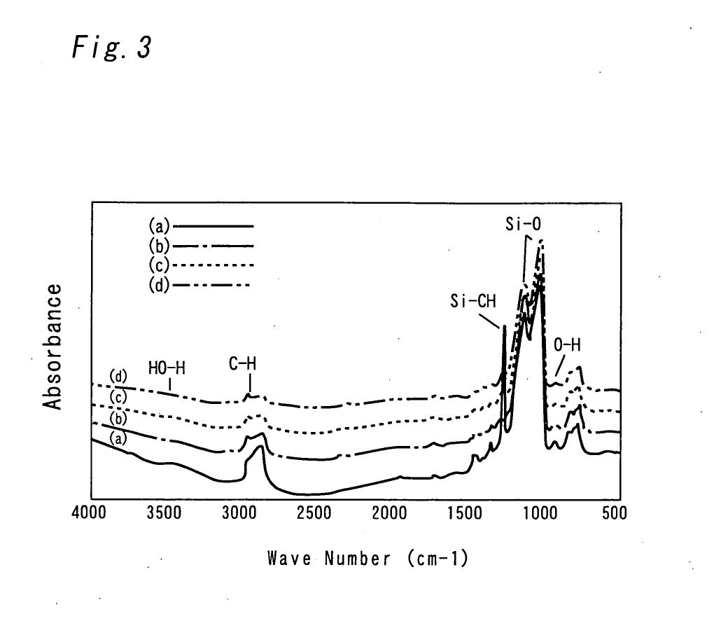

FIG. 3 shows infrared absorption spectra of the MSQ film, obtained right after the heat treatment at 200° C. and right after the plasma treatment. Specifically, in FIG. 3, line (a) indicates a spectrum obtained right after the heat treatment, while lines (b), (c), and (d) indicate spectra obtained when the plasma treatment time is set to 5, 10, and 15 seconds, respectively.

Referring to FIG. 3, the absorption observed in the neighborhood of 2,800 cm⁻¹ to 3,000 cm⁻¹ is attributed to the organic component contained in the MSQ film. As can be seen from the figure, the absorption level obtained right after the heat treatment is highest, and the absorption level decreases with increasing plasma treatment time. The absorption observed in the neighborhood of 3,500 cm⁻¹ is attributed to water. The level of this absorption is reduced through the plasma treatment.

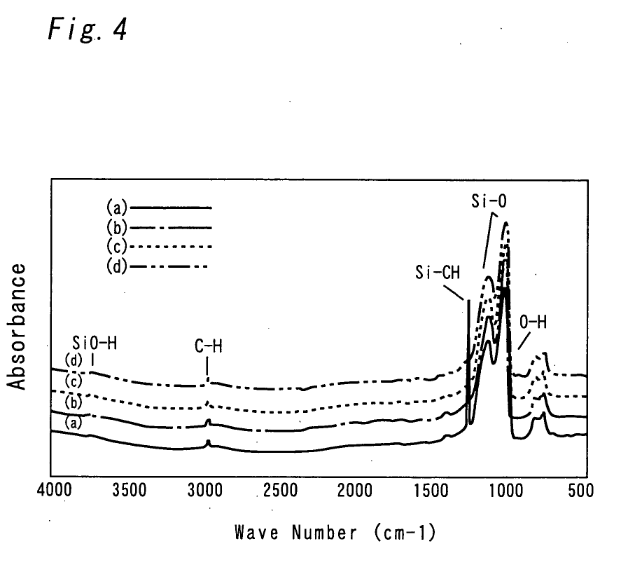

After the plasma treatment, the MSQ film is heat treated at a temperature of approximately 450° C. FIG. 4 shows infrared absorption spectra of the sample of FIG. 3, obtained right after the heat treatment at approximately 450° C. Specifically, in FIG. 4, line (a) indicates a spectrum obtained right after heat treatment at 450° C. which immediately followed heat treatment at 200° C. without performing plasma treatment. Lines (b), (c), and (d) indicate spectra obtained right after heat treatment at 450° C. which followed heat treatment at 200° C. and plasma treatment. The plasma treatment time is set to 5, 10, and 15 seconds, respectively.

As can be seen from the figure, the absorption of the organic component observed in the neighborhood of 2,800 cm⁻¹ to 3,000 cm⁻¹ in FIG. 3 has disappeared. Further, the spectra (b), (c), and (d) each exhibit no large change, which indicates that no considerable damage was inflicted to the film even when the plasma treatment time was set to 15 seconds.

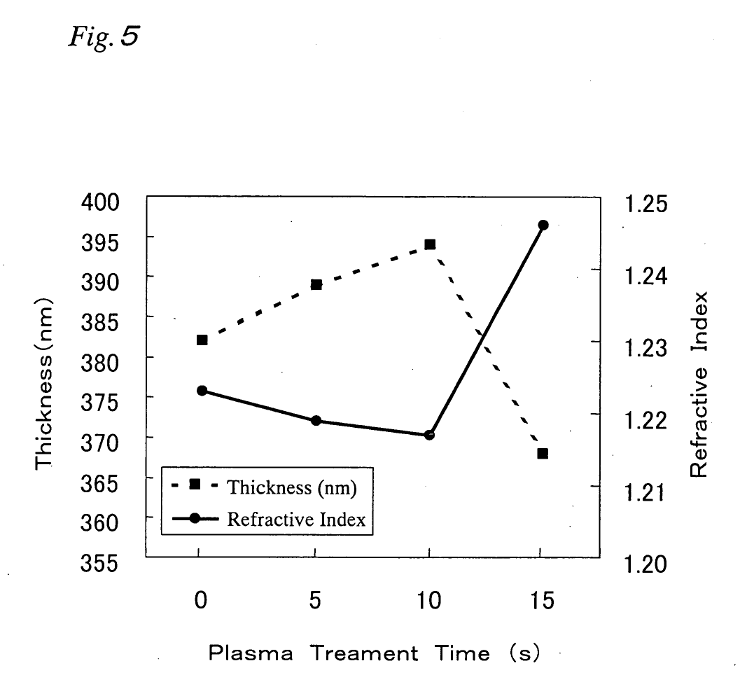

FIG. 5 shows how the film thickness and the refractive index of the sample of FIG. 4 change with the plasma treatment time. It should be noted that the measurement was made by a spectral ellipsometry method, assuming the sample as a single layer film. As can be seen from the figure, the film thickness increases and the refractive index decreases with increasing plasma treatment time (until the plasma treatment time reaches 10 seconds). However, the film thickness rapidly decreases and the refractive index rapidly increases as the plasma treatment time increases from 10 seconds to 15 seconds.

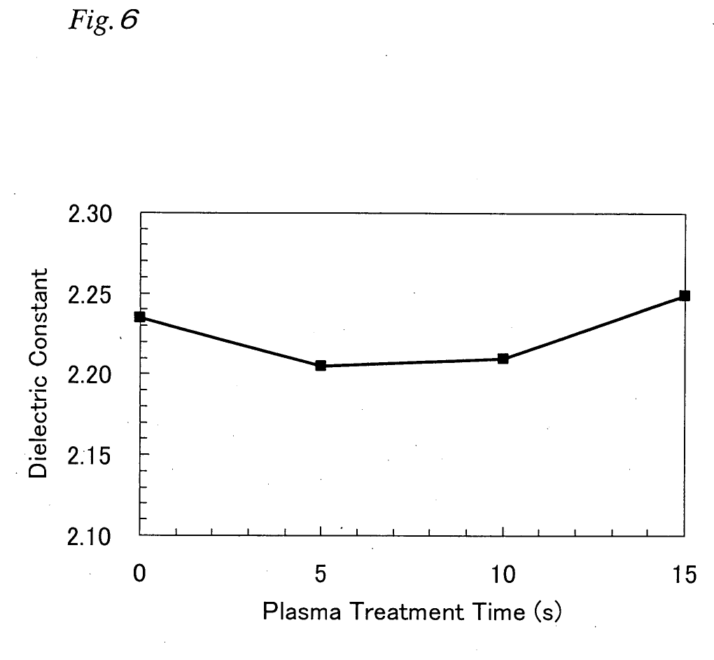

FIG. 6 shows how the dielectric constant changes with the plasma treatment time. FIG. 6 was obtained based on the film thickness measurements shown in FIG. 5 and capacitance measurements. As can be seen from the figure, the dielectric constant decreases with increasing plasma treatment time (until the plasma treatment time reaches 10 seconds). This is considered to be attributed to the fact that the plasma treatment decomposes and removes the organic component within the MSQ film and therefore the void content of the film is increased, as compared to when the film is only heat treated. However, the dielectric constant increases as the plasma treatment time increases from 10 seconds to 15 seconds. This is considered to be attributed to the fact that a large number of silanol groups are generated after the plasma treatment and therefore some silanol groups remain within the film even after the heat treatment.

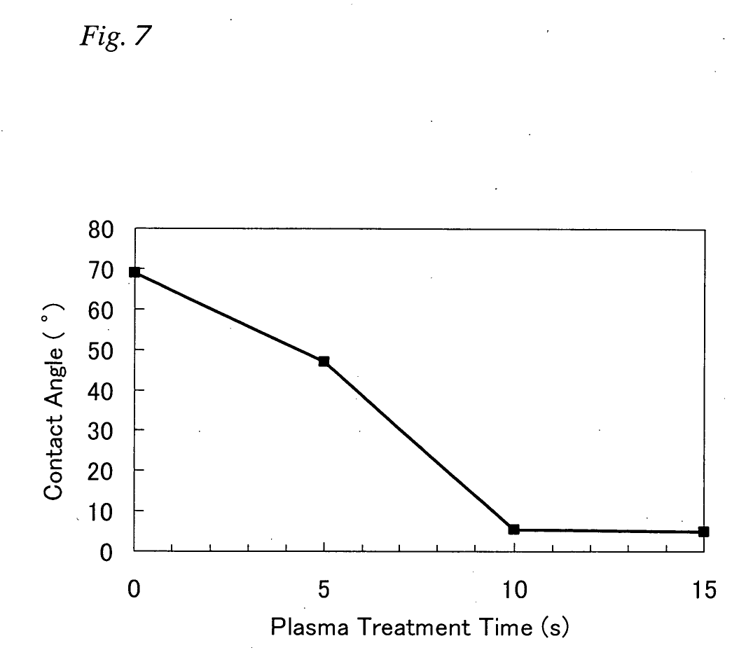

FIG. 7 shows how the contact angle of the sample of FIG. 5 changes with the plasma treatment time. As can be seen from the figure, the film exhibits full hydrophilicity after the plasma treatment time reaches 10 seconds. This is considered to be attributed to the fact that carbon (atoms) within the MSQ film is substituted by oxygen (atoms) and thereby a modifying layer is formed on the surface. Formation of such a hydrophilic modifying layer provides sufficient adhesion when a silicon oxide film is formed thereon.

Description will be made below of a conventional method for forming the insulating film, for comparison.

By a coating technique, an MSQ film containing an organic component is formed on a silicon nitride film formed on a silicon substrate. After heat treating the MSQ film (and other components) at a temperature of approximately 450° C., plasma treatment is applied to it using N₂O gas. For example, N₂O gas mixed with Ar gas acting as a dilution gas is introduced into a vacuum chamber maintain at a pressure of 1,000 Pa. At that time, the flow rate of the N₂O gas and that of the Ar gas are set to 200 ccm and 1,000 ccm, respectively. 13.56 MHz RF power of 200 W may be applied between the opposing electrodes to perform plasma treatment on the MSQ film. It should be noted that the temperature of the substrate is set to approximately 250° C. in the plasma treatment process.

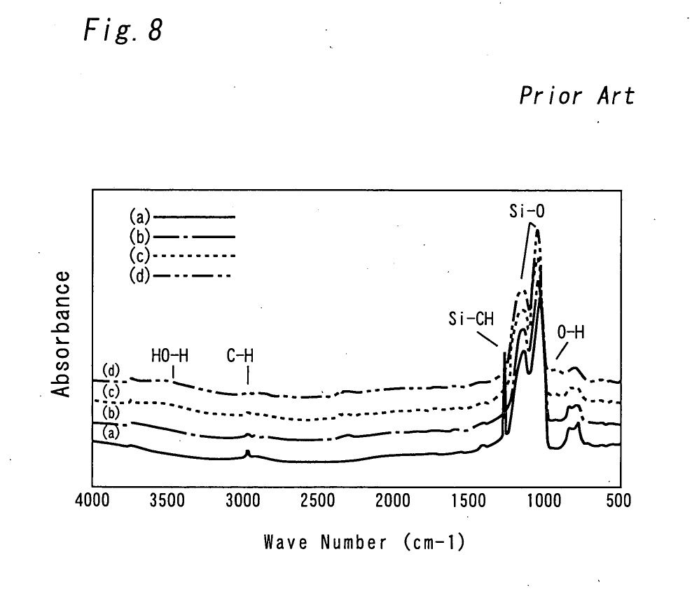

FIG. 8 shows infrared absorption spectra of the MSQ film, obtained (right after the heat treatment and) right after the plasma treatment. Specifically, in FIG. 8, line (a) indicates a spectrum obtained right after the heat treatment, while lines (b), (c), and (d) indicate spectra obtained when the plasma treatment time is set to 5, 10, and 15 seconds, respectively.

Referring to FIG. 8, the absorption observed in the neighborhood of 1,200 cm⁻¹ is attributed to the methyl groups. As can be seen from the figure, the absorption level decreases with increasing plasma treatment time. This occurs due to substitution of oxygen (atoms) within the plasma for carbon (atoms) of the methyl groups. The absorption observed in the neighborhood of 3,500 cm⁻¹, on the other hand, is attributed to water. The level of this absorption is increased through the plasma treatment.

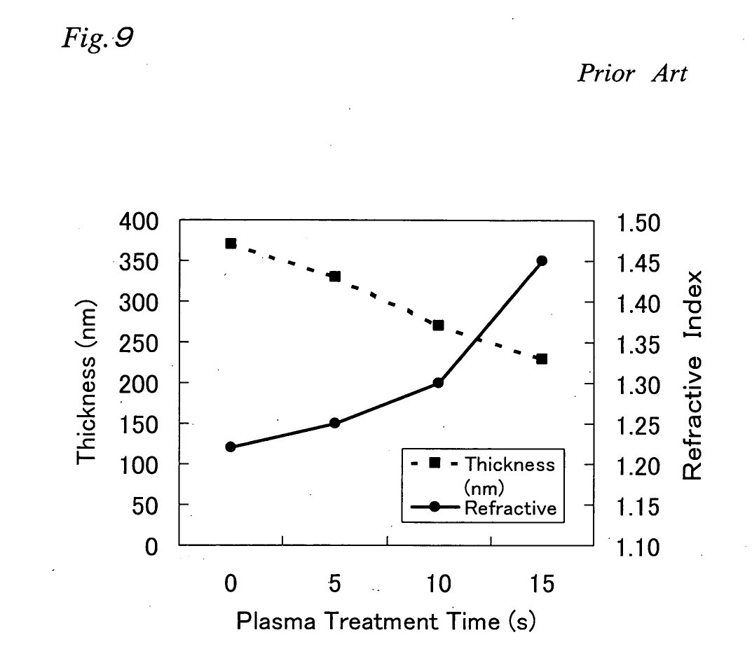

FIG. 9 shows how the film thickness and the refractive index of the sample of FIG. 8 change with the plasma treatment time. It should be noted that the measurement was made by a spectral ellipsometry method, assuming the sample as a single layer film. As can be seen from the figure, the film thickness rapidly decreases and the refractive index rapidly increases with increasing plasma treatment time.

The present embodiment applies plasma treatment to the insulating film so as to form a modifying layer thereon, thereby enhancing its adhesion to the silicon oxide film. Therefore, defects such as peeling of a film can be reduced, making it possible to enhance the yield of the semiconductor manufacturing process and manufacture highly reliable semiconductor devices.

Further, the present embodiment decomposes and vaporizes the organic component (or decomposes the organic siloxane) in the plasma treatment process and the heat treatment process following it so as to remove substantially the entire organic component contained in the insulating film, making it possible to increase the void content of the film and thereby reduce the dielectric constant. Therefore, the parasitic capacitance of the semiconductor device can be considerably reduced, which leads to a reduction in a signal delay due to miniaturization.

Still further, the present embodiment causes silanol groups generated after the plasma treatment to react (with moisture) through heat treatment, making it possible to reduce the hygroscopicity of the film and thereby prevent an increase in the dielectric constant.

It should be noted that even though the present embodiment was described as applied to an insulating film for forming wiring, the present invention is not limited to this particular application. The present invention can be applied to formation of a porous film having good adhesion to an inorganic film.

The features and advantages of the present invention may be summarized as follows.

According to one aspect, the method of the present invention can be used to form a low dielectric insulating film having good adhesion to a silicon oxide film, making it possible to reduce the parasitic capacitance of the device and thereby reduce the signal delay due to miniaturization. Furthermore, defects such as peeling of a film can be reduced, making it possible to enhance the yield of the semiconductor manufacturing process and manufacture high reliable semiconductor devices.

Obviously many modifications and variations of the present invention are possible in the light of the above teaching. It is therefore to be understood that within the scope of the appended claims the invention may be practiced otherwise than as specifically described.

The entire disclosure of a Japanese Paten Application No. 2003-082766, filed on Mar. 25, 2003 including specification, claims, drawings and summary, on which the Convention priority of the present application is based, are incorporated herein by reference in its entirety.

What is claimed is:

1. A method for manufacturing a semiconductor device, said method comprising the steps of:
forming an insulating film on a semiconductor base material, said insulating film being predominantly composed of organic siloxane and containing an organic component which has no chemical bond to said organic siloxane; and
applying plasma treatment to said insulating film to remove said organic component and form a modifying layer on a surface of said insulating film.

2. The method for manufacturing a semiconductor device according to claim 1, wherein said insulating film forming step is performed by a chemical vapor deposition method.

3. The method for manufacturing a semiconductor device according to claim 1, wherein said insulating film forming step includes steps of:
coating said semiconductor base material with an insulating film composition containing said organic siloxane and said organic component; and
heat treating said insulating film composition at a temperature between 100° C. and 200° C.

4. The method for manufacturing a semiconductor device according to claim 1, wherein said plasma treatment is performed using a gas containing at least one selected from the group consisting of oxygen, hydrogen and nitrogen.

5. The method for manufacturing a semiconductor device according to claim 1, wherein molecules of said organic siloxane contain an alkyl group or an allyl group.

6. The method for manufacturing a semiconductor device according to claim 5, wherein said organic siloxane is MSQ.

7. The method for manufacturing a semiconductor device according to claim 1, further comprising a step of:
after said plasma treatment, heat treating said insulating film at a temperature between 250° C. and 450° C.

8. The method for manufacturing a semiconductor device according to claim 1, further comprising a step of:
after said plasma treatment, heat treating said insulating film at a temperature between 400° C. and 450° C.

9. A method for manufacturing a semiconductor device, said method comprising the steps of:
forming an insulating film on a semiconductor base material, said insulating film being composed of organic siloxane; and
applying plasma treatment to said insulating film to remove an organic group from said organic siloxane and form a modifying layer on a surface of said insulating film.

10. The method for manufacturing a semiconductor device according to claim 9, wherein said insulating film forming step is performed by a chemical vapor deposition method.

11. The method for manufacturing a semiconductor device according to claim 9, wherein said insulating film forming step includes steps of:
coating said semiconductor base material with an insulating film composition containing said organic siloxane and said organic component; and
heat treating said insulating film composition at a temperature between 100° C. and 200° C.

12. The method for manufacturing a semiconductor device according to claim 9, wherein said plasma treatment is performed using a gas containing at least one selected from the group consisting of oxygen, hydrogen and nitrogen.

13. The method for manufacturing a semiconductor device according to claim 9, wherein molecules of said organic siloxane contain an alkyl group or an allyl group.

14. The method for manufacturing a semiconductor device according to claim 13, wherein said organic siloxane is a phenyl methyl siloxane.

15. The method for manufacturing a semiconductor device according to claim 9, further comprising a step of:
after said plasma treatment, heat treating said insulating film at a temperature between 250° C. and 450° C.

16. The method for manufacturing a semiconductor device according to claim 9, further comprising a step of:
after said plasma treatment, heat treating said insulating film at a temperature between 400° C. and 450° C.
